(19) United States
(12) Patent Application Publication
(10) Pub. No.: US 2002/0075036 A1
(43) Pub. Date: Jun. 20, 2002

(54) Circuit for eliminating floating inputs on differential receivers

(76) Inventor: Stephen M. Nolan, Van Alstyne, TX (US)

Correspondence Address: TEXAS INSTRUMENTS INCORPORATED, P O BOX 655474, M/S 3999, DALLAS, TX, 75265

(21) Appl. No.: 10/006,531

(22) Filed: Dec. 5, 2001

Related U.S. Application Data
(60) Provisional application No. 60/256,885, filed on Dec. 19, 2000.

(51) Int. Cl. H03K 19/0175

(52) U.S. Cl. 326/83

(57) ABSTRACT

The differential circuit includes: a first transistor 20; a second transistor 22 having a first end coupled to a first end of the first transistor 20 to form a differential pair; a first resistor 42 coupled between a second end of the first transistor 20 and a control node of the second transistor 22; and a second resistor 40 coupled between a second end of the second transistor 22 and a control node of the first transistor 20. This circuit ensures that the differential inputs 30 and 32 and are held complimentary which avoids a floating input condition, reduces susceptibility to noise and oscillation, and keeps the power supply current low.

### FIELD OF THE INVENTION

This invention generally relates to electronic systems and in particular it relates to eliminating floating inputs on differential receivers.

### BACKGROUND OF THE INVENTION

A typical prior art differential input receiver is shown in FIG. 1. The prior art circuit of FIG. 1 includes differential transistors 20 and 22; resistors 24 and 26; current source 28; input nodes 30 and 32; output nodes 34 and 36; and power supply voltage Vcc. This prior art circuit experiences high power supply current if the inputs are floating (undriven). Floating inputs will cause indeterminate input voltages which will cause noise and oscillation problems. A prior art solution to this problem in a single-ended circuit is a bus-hold technique. However, in a differential circuit, the bus-hold solution does not guarantee that the inputs are held in a complimentary state.

### SUMMARY OF THE INVENTION

A differential circuit includes: a first transistor; a second transistor having a first end coupled to a first end of the first transistor to form a differential pair; a first resistor coupled between a second end of the first transistor and a control node of the second transistor; and a second resistor coupled between a second end of the second transistor and a control node of the first transistor. This circuit ensures that the differential inputs and are held complimentary which avoids a floating input condition, reduces susceptibility to noise and oscillation, and keeps the power supply current low.

### BRIEF DESCRIPTION OF THE DRAWINGS

In the drawings:

FIG. 1 is a schematic circuit diagram of a typical prior art differential input receiver;

FIG. 2 is a schematic circuit diagram of a preferred embodiment differential input receiver.

### DETAILED DESCRIPTION OF PREFERRED EMBODIMENTS

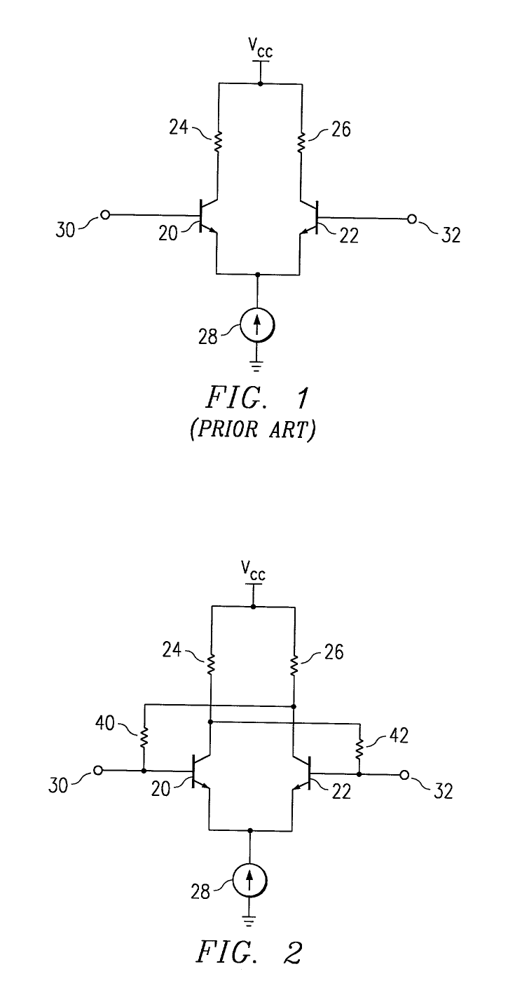

FIG. 2 shows a preferred embodiment differential input receiver. The preferred embodiment circuit of FIG. 2 includes the same components as the prior art circuit of FIG. 1 with the addition of resistors 40 and 42. The addition of weak resistors 40 and 42 creates a bistable circuit that will force itself into a valid state. This is similar to the functionality of a bus-hold cell on a single-ended input. The operation of the preferred embodiment circuit of FIG. 2 is similar to a bistable flip-flop. The advantage of this solution is that the inputs 30 and 32 are held complimentary which keeps the power supply current low. Resistors 40 and 42 have small resistance values so that only a minimal amount of additional current will be drawn from the input nodes 30 and 32.

While this invention has been described with reference to an illustrative embodiment, this description is not intended to be construed in a limiting sense. Various modifications and combinations of the illustrative embodiment, as well as other embodiments of the invention, will be apparent to persons skilled in the art upon reference to the description. For example, NPN transistors 20 and 22 can be replaced with other types of transistors. It is therefore intended that the appended claims encompass any such modifications or embodiments.

What is claimed is:

1. A differential circuit comprising:
a first transistor;
a second transistor having a first end coupled to a first end of the first transistor to form a differential pair;
a first resistor coupled between a second end of the first transistor and a control node of the second transistor; and
a second resistor coupled between a second end of the second transistor and a control node of the first transistor.

2. The circuit of claim 1 further comprising a current source coupled to the first end of the first transistor.

3. The circuit of claim 1 further comprising:
a third resistor having a first end coupled to the second end of the first transistor; and
a fourth resistor having a first end coupled to the second end of the second transistor.

4. The circuit of claim 2 further comprising:
a third resistor coupled to the second end of the first transistor; and
a fourth resistor coupled to the second end of the second transistor.

5. The circuit of claim 3 wherein a second end of the third resistor is coupled to a second end of the fourth resistor.

6. The circuit of claim 1 wherein the first and second transistors are bipolar transistors.
